(19) United States
(12) Patent Application Publication
(10) Pub. No.: US 2009/0305165 A1
(43) Pub. Date: Dec. 10, 2009

(54) WAFER EXPOSING METHOD, EUV EXPOSING APPARATUS, AND EB EXPOSING APPARATUS

(76) Inventors: Ryoichi INANAMI, Kanagawa (JP); Tatsuhiko HIGASHIKI, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/478,646

(22) Filed: Jun. 4, 2009

(30) Foreign Application Priority Data
Jun. 5, 2008 (JP) 2008-148346

(51) Int. Cl. G03F 7/20; G03B 27/42

(52) U.S. Cl. 430/311; 355/53

(57) ABSTRACT

A wafer exposing method comprising EUV-exposing a product area, which is formed as a product chip, on a wafer and EB-exposing a peripheral area on the wafer, wherein the EB exposure of a wafer different from the wafer being EUV-exposed is performed while the EUV exposure of the wafer is performed.

### CROSS-REFERENCE TO RELATED APPLICATIONS

This application is based upon and claims the benefit of priority from the prior Japanese Patent Application No. 2008-148346, filed on Jun. 5, 2008; the entire contents of which are incorporated herein by reference.

### BACKGROUND OF THE INVENTION

1. Field of the Invention

The present invention relates to a wafer exposing method, an extreme ultraviolet (EUV) exposing apparatus, and an electron beam (EB) exposing apparatus.

2. Description of the Related Art

There is an EUV exposing apparatus employing extreme ultraviolet (EUV) light as an exposing apparatus for performing microprocessing for semiconductor devices and the like. The EUV light used in the EUV exposing apparatus (EUV lithography) is light (an X ray) having the wavelength around 13.5 nm, which is shorter than the wavelength (193 nm or 248 nm) of light used in the light exposure in the past. Therefore, the EUV lithography is prospective as a method of forming a fine pattern on a wafer.

The throughput of exposure by the EUV exposing apparatus is predicted to be inferior to the throughput of the conventional light exposing apparatus because of factors such as resist sensitivity, power of irradiated EUV light, and overhead time due to installation of a wafer in a vacuum chamber. As a method of improving the throughput of EUV exposure, for example, there is a method of omitting shot exposure to a shot (a cut shot) (imperfect shot) including an area, from which a product chip is not produced, on a wafer. In this method, the coverage of a pattern (a resist during machining) of the entire wafer cannot be kept uniform. Therefore, a pattern having a uniform shape over the entire wafer cannot be formed. In some case, resist peeling or the like occurs in the periphery of the wafer.

Therefore, the EUV exposing apparatus needs to perform peripheral exposure while improving throughput. For example, an electron beam (EB) exposing apparatus disclosed in Japanese Patent Application Laid-Open No. 2000-58413 irradiates, in performing peripheral exposure of a wafer, an electron beam on an irradiation area larger than that during exposure of a molded chip (a product chip) to perform the peripheral exposure more quickly than the exposure of the product chip. However, in the technologies in the past, control of an EB irradiation amount and an electronic lens in performing the peripheral exposure of a wafer is complicated.

### BRIEF SUMMARY OF THE INVENTION

A wafer exposing method according to an embodiment of the present invention comprises: EUV-exposing a product area, which is formed as a product chip, on a wafer and EB-exposing a peripheral area on the wafer, wherein the EB exposure of a wafer different from the wafer being EUV-exposed is performed while the EUV exposure of the wafer is performed.

An EUV exposing apparatus according to an embodiment of the present invention comprises: an EUV-exposure processing unit that EUV-exposes a product area, which is formed as a product chip, on a wafer; and an EB-exposure processing unit that EB-exposes a peripheral area on the wafer, wherein the EB-exposure processing unit EB-exposes, while the EUV-exposure processing unit EUV-exposes a wafer, a wafer different from the wafer EUV-exposed by the EUV-exposure processing unit.

An EB exposing apparatus according to an embodiment of the present invention comprises: an EUV-exposure processing unit that EUV-exposes a product area, which is formed as a product chip, on a wafer; and an EB-exposure processing unit that EB-exposes a peripheral area on the wafer, wherein the EUV-exposure processing unit EUV-exposes, while the EB-exposure processing unit EB-exposes a wafer, a wafer different from the wafer EB-exposed by the EB-exposure processing unit.

### BRIEF DESCRIPTION OF THE DRAWINGS

FIG. 1 is a diagram of a configuration of an exposing apparatus according to an embodiment of the present invention;

FIG. 2 is a perspective view of a configuration of an EB exposing unit;

FIG. 3A is a diagram of a pattern example of an EB forming aperture;

FIG. 3B is a diagram of a pattern example of an EB forming aperture;

FIG. 3C is a diagram of a pattern example of an EB forming aperture;

FIG. 4A is a diagram for explaining the arrangement of an EUV exposure area and an EB exposure area;

FIG. 4B is a diagram for explaining the arrangement of an EUV exposure area and an EB exposure area;

FIG. 5A is a diagram for explaining an EB exposure area used for calculation of electron beam size;

FIG. 5B is a diagram for explaining an EB exposure area used for calculation of electron beam size; and

FIG. 6 is a flowchart of an exposure processing procedure for a wafer.

### DETAILED DESCRIPTION OF THE INVENTION

Exemplary embodiments of the present invention are explained in detail below with reference to the accompanying drawings. The present invention is not limited by the embodiments.

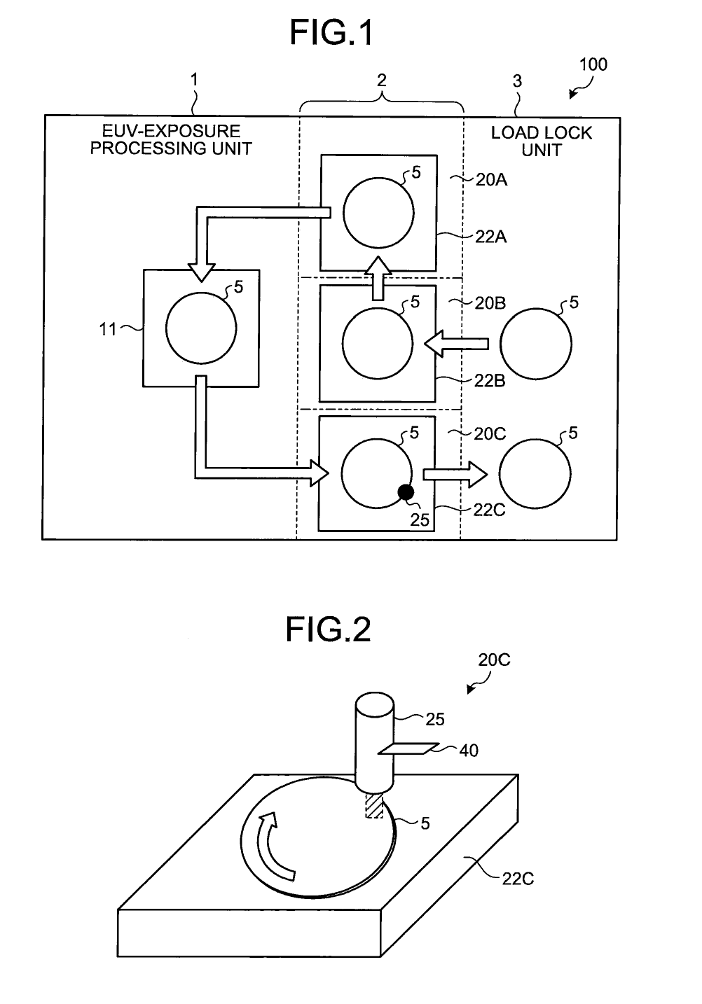

FIG. 1 is a diagram of a configuration of an exposing apparatus according to an embodiment of the present invention. A top view of the exposing apparatus is shown in FIG. 1. An exposing apparatus 100 is an apparatus that performs peripheral exposure of a wafer with EB exposure in standby time of EUV exposure. The exposing apparatus 100 includes an EUV-exposure processing unit, a wafer robot unit 2, and a load lock unit 3.

The EUV-exposure processing unit (an EUV exposing apparatus) 1 exposes a wafer 5 with extreme ultraviolet (EUV) light. The EUV-exposure processing unit 1 is arranged adjacent to the wafer robot unit 2. The EUV-exposure processing unit 1 places the wafer 5, which is carried from the wafer robot unit 2, on a wafer stage (an exposure stage) 11 and EUV-exposes the wafer 5. The EUV-exposure processing unit 1 according to this embodiment EUV-exposes an area, which is formed as a product chip (a main body chip), of the wafer 5 (a product area). The EUV-exposure processing unit 1 carries the wafer 5 out to the wafer robot unit 2 after the exposure. The wafer robot unit 2 can carry out the wafer after the exposure from the EUV-exposure processing unit 1.

The wafer robot unit (a wafer robot chamber) 2 is arranged between the EUV-exposure processing unit 1 and the load lock unit 3. The wafer robot unit 2 includes an alignment unit 20A, a wafer loader 20B, and an EB exposing unit 20C. The wafer loader 20B carries the wafer 5 into the unit 20B (itself unit) which is carried from the load lock unit 3, and places the wafer 5 on a wafer stage 22B. The wafer loader 20B carries the wafer 5 placed on the wafer stage 22B to the alignment unit 20A.

The alignment unit 20A is arranged adjacent to the wafer loader 20B. The alignment unit 20A places the wafer 5, which is carried from the wafer loader 20B, on a wafer stage 22A and aligns the wafer 5. The alignment unit 20A carries the aligned wafer 5 to the EUV-exposure processing unit 1.

The EB exposing unit (an EB irradiating unit) 20C exposes the wafer 5 with an electron beam (EB). The EB exposing unit 20C places the wafer 5, which is carried from the EUV-exposure processing unit 1, on a wafer stage 22C and EB-exposes the wafer 5. The EB exposing unit 20C according to this embodiment EB-exposes an area, which is not formed as a product chip, of the wafer 5 (a non-product area in which a dummy pattern is arranged) using an EB irradiation column 25. The wafer robot unit 2 carries the wafer 5 out to the load lock unit 3 after the EB exposure.

The load lock unit 3 is a vacuum chamber for carrying in the wafer 5 to the wafer robot unit 2 such that the wafer robot unit 2 (the EUV-exposure processing unit 1) is not exposed to the atmosphere. The load lock unit 3 and the wafer robot unit 2 are partitioned by a gate valve (not shown). The wafer 5 is carried between the load lock unit 3 and the wafer robot unit 2 via the gate valve.

The gate valve is closed when the wafer 5 before exposure is set in the load lock unit 3 from the outside and when the wafer 5 after exposure is taken out to the outside from the load lock unit 3. The gate valve is opened when the wafer 5 before exposure is carried from the load lock unit 3 to the wafer robot unit 2 and when the wafer 5 after exposure is carried from the wafer robot unit 2 to the load lock unit 3. The wafer 5 is set in the load lock unit 3 in, for example, lot units.

The EUV-exposure processing unit 1 according to this embodiment EUV-exposes, shot by shot (EUV shot units), the center of the wafer 5, which is formed as a product area. The EB exposing unit 20C EB-exposes, shot by shot (EB shot units), a peripheral section (a peripheral area) of the wafer 5, which is formed as a dummy area.

In the following explanation, an area EUV-exposed by the EUV-exposure processing unit 1 in the wafer 5 is explained as an EUV exposure area and an area EB-exposed by the EB exposing unit 20C in the wafer 5 is explained as an EB exposure area.

When the wafer 5 is exposed by an EUV shots, if an entire area in one EUV shot can be exposed on the wafer 5, this area is set as an EUV exposure area (an EUV shot). On the other hand, if the entire area in one EUV shot cannot be exposed on the wafer 5 (the EUV shot protrudes from the wafer 5), this area is set as an EB exposure area. In other words, an EUV shot (a cut shot) (imperfect shot) including an area, which is not formed as a product chip, on the wafer 5 is not set as an EUV exposure area but is set as an EB exposure area.

FIG. 2 is a diagram of a configuration of the EB exposing unit 20C. The EB exposing unit 20C includes the EB irradiation column 25 having an EB forming aperture 40 and the wafer stage 22C.

The EB irradiation column 25 is set on an outer circumference of the wafer 5 and forms an EB irradiated on the wafer 5 using the EB forming aperture 40. The EB forming aperture 40 passes a part of the EB in the EB irradiation column 25 and irradiates the EB on the wafer 5. Only the EB passing through the EB forming aperture 40 is irradiated on the wafer 5, whereby a pattern formed on the EB forming aperture 40 is exposed on the wafer 5. The pattern formed on the EB forming aperture 40 is a dummy pattern such as a line and a hole.

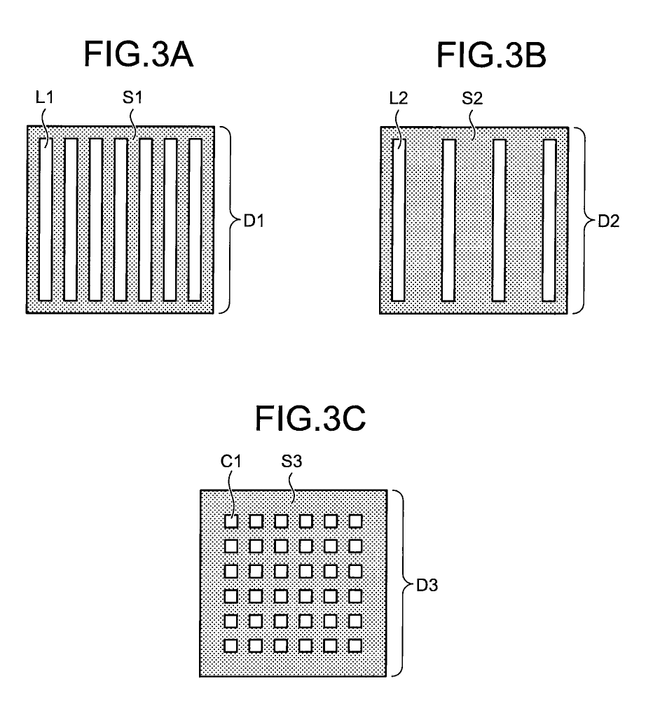

In the EB forming aperture 40, a pattern having the same coverage (a pattern formation ratio) during etching in an EUV exposure area and an EB exposure area is formed. In other words, the EB forming aperture 40 that can form a pattern having coverage same as that of a pattern formed by using an EUV shot is selected and set in the exposing apparatus 100. For example, the EB forming aperture 40 corresponding to the coverage and a pattern shape (a type of a pattern) of a product chip is selected from the EB forming apertures 40 shown in FIGS. 3A to 3C and set in the exposing apparatus 100.

A pattern Dl of the EB forming aperture 40 shown in FIG. 3A includes lines L1 and spaces S1. The coverage of the pattern D1 is 50%. A pattern D2 of the EB forming aperture 40 shown in FIG. 3B includes lines L2 and spaces S2. The coverage of the pattern D2 is 25%. A pattern D3 of the EB forming aperture 40 shown in FIG. 3C includes a pattern in which contacts C1 are arranged in array and a patter S3 excluding the contacts C1. The coverage of the pattern D3 is 25%. In FIGS. 3A to 3C, an EB passes through the lines L1 and L2 and the contacts C1 and is blocked by the spaces S1 and S2 and the pattern S3. The coverage of each of the EB forming apertures 40 shown in FIGS. 3A to 3C is a ratio of an area through which the EB passes to an area of the EB forming aperture 40. The EB forming aperture 40 is opened at a ratio corresponding to the coverage. In other words, the EB exposing unit 20C adjusts the coverage of a pattern exposed on the peripheral section (the EB exposure area) of the wafer 5 according to the number of patterns formed in the EB forming aperture 40.

When the EB forming aperture 40 is selected, the EB forming aperture 40 which having a pattern shape similar to a pattern shape and the same coverage in a product chip section is selected. For example, when the product chip section includes lines and spaces, the EB forming aperture 40 including the lines and the spaces is selected. When the coverage of the product chip section is 50%, the EB forming aperture 40 having the coverage of 50% is selected.

The coverage of a pattern of a product chip section is the same in the same wafer 5 or the same lot. Therefore, an irradiation pattern corresponding to each lot only has to be selected and used in the EB forming aperture 40. Consequently, an electro-optical system of the EB exposing section 20C is not complicated. The exposing apparatus 100 can perform EB exposure with a simple configuration.

The wafer stage 22C has a wafer rotating mechanism that rotates the wafer 5 in a plane parallel to a main plane of the wafer 5 (in a wafer plane). The wafer stage 22C places the wafer 5 thereon and, when the wafer 5 is EB-exposed, rotates the wafer 5. The wafer rotating mechanism of the wafer stage 22C rotates the wafer 5 with an axis passing through the center of the wafer 5 set as a rotation axis. The EB exposing unit 20C according to this embodiment does not perform EB irradiation on a product chip section on the wafer 5. Therefore, the EB exposing unit 20C performs EB exposure while controlling an EB irradiation position to irradiate the EB only on an outer periphery of the wafer 5.

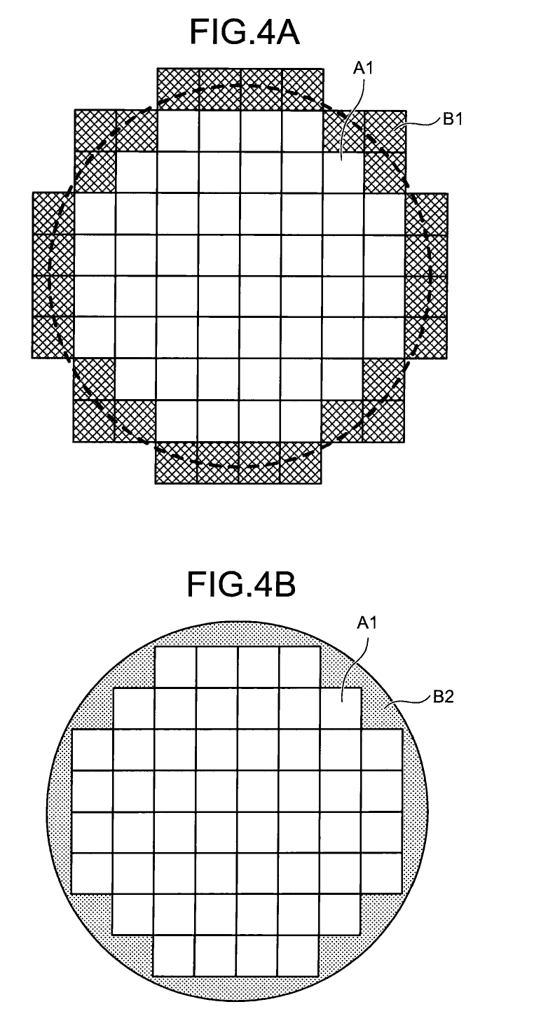

FIGS. 4A and 4B are diagrams for explaining an EUV exposure area and an EB exposure area. To set an EUV exposure area and an EB exposure area on the wafer 5, a plane of the wafer 5 is sectioned into areas of shot size same as the size of the EUV shot. Each shot is set as an area in which exposure is performed by the EUV shot or an area in which EB exposure is performed.

Specifically, when all areas for one shot are fit in the plane of the wafer 5 without protruding from the wafer 5, the shot is set as an EUV shot (an EUV exposure area). When at least a part of a shot protrudes from the wafer 5, the shot is set as an EB exposure area. For example, when four product chips are arranged in one EUV shot, a shot that can expose all the four chips on the wafer 5 without protruding from the wafer 5 is the EUV shot. However, even when a plurality of product chips included in one shot protrudes from the plane of the wafer 5, the shot may be set as the EUV shot when necessary.

In FIG. 4A, the EUV shot is indicated by an EUV shot area A1. A shot not set as the EUV shot is indicated by a shot area B1. A shot in an area on an inner side of the wafer 5 is the EUV shot area A1. A shot in an area on an outer side of the wafer 5 is the shot area B1.

The EUV shot area A1 is EUV-exposed for each EUV shot. On the other hand, only the shot area B1 in the inside of the wafer 5 has to be EB-exposed. An area outside of the wafer 5 does not need to be EB-exposed. Therefore, an area actually EB-exposed on the wafer 5 is an EB exposure area B2 shown in FIG. 4B. The EB exposure area B2 is an area excluding an area outside the wafer 5 from the shot area B1. In other words, an area on the wafer 5 excluding the EUV shot area A1 is the EB exposure area B2.

The EUV shot area A1 on the inner side of the wafer 5 includes EUV shots in which product chips are actually formed. The EB exposure area B2 in the periphery of the wafer 5 includes EB shots in which any product chips are not formed. The EB exposure area B2 is EB-exposed by a plurality of EB shots. Because the EB exposure area B2 is in the outer periphery of the wafer 5, the EB exposing unit 20C according to this embodiment exposes the EB exposure area B2 using the EB irradiation column 25 while rotating the wafer 5. Consequently, the EB exposing unit 20C can be set in the exposing apparatus 100 with a small setting area. The EB exposing unit 20C can easily control an EB irradiation position.

A resist exposed by the EUV exposure is also exposed by the EB exposure. Therefore, the exposing apparatus 100 can easily expose the periphery of the wafer 5 with a simple configuration.

When electron beam size (an area of an EB shot) during the EB exposure by the EB exposing unit 20C is small, long time is required as EB exposure time for the EB exposure area in the wafer 5. In this embodiment, to set processing time of the EB exposure by the EB exposing unit 20C shorter than a predetermined time, the EB exposing unit 20C is configured to have electron beam size larger than a predetermined value. For example, the EB exposure is performed by using an EB having electron beam size with which processing time for the EB exposure by the EB exposing unit 20C in exposing one wafer 5 is shorter than processing time for the EUV exposure by the EUV-exposure processing unit 1.

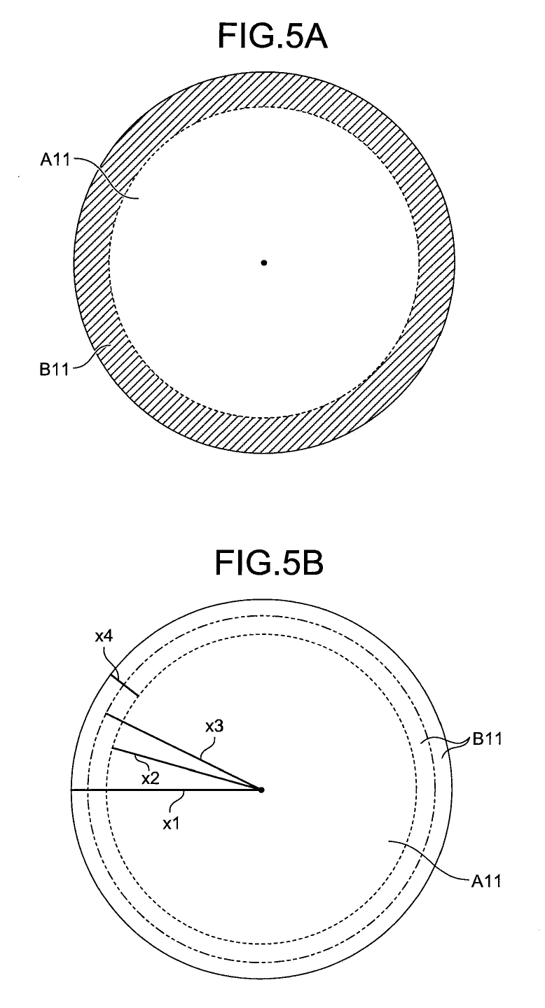

FIGS. 5A and 5B are diagrams for explaining a method of calculating electron beam size. To facilitate understanding of explanation, an EUV exposure area is assumed as a circular area A11 shown in FIG. 5A and an EB exposure area is assumed as an annular area B11 shown in FIG. 5A.

As shown in FIG. 5B, it is assumed that a radius x1 of the wafer 5 is, for example, 150 millimeters. It is assumed that, for example, a radius x2 of the area A11 is 120 millimeters and width x4 of the area B11 is 30 millimeters. An average radius x3 of the area B11 in this case is 135 millimeters.

An area Sx of the EB exposure area (the area B11) as a target of EB exposure in this case is Sx=(150²−120²)π=8100π (mm²). Length Lx of the area B11 is Lx=2π·135=270π (mm).

It is assumed that the throughput of the EB exposing unit 20C is 100 (wph: wafer per hour), current density is 10 (A/cm²), resist sensitivity is 10 (μC/cm²), and EB shot settling time is 1 microsecond. The throughput of the EB exposing unit 20C is set to 100 wph because the throughput of the EUV exposing unit 1 is assumed to be 100 wph.

Because the throughput of the EB exposing unit 20C is 100 (wph), exposure processing time (second) required for one wafer 5 is 3600/100=36 (s/Wafer). In other words, time required for EB exposure of one wafer 5 is 36 seconds. Because the area Sx of the area B11 is 8100π (mm²), an area EB-exposed in one second is 8100π÷36=225π (mm²/s).

Time required for exposure for one shot of an EB shot is 10 (μC/cm²)÷10 (A/cm²). To perform shot exposure while changing a shot position of each EB shot with a deflector shot by shot, settling time of an amplifier for driving the deflector is necessary. Therefore, total time (2 μs) of the time (1 μs) required for exposure for one shot of the EB shot and the EB shot settling time (1 μs) is time required for one shot of EB exposure processing. An area per one shot of the EB shot is 225π×2(μs)=450π×10⁻⁶(mm²/shot=1413.7 (μm²/shot).

Therefore, electron beam size of an EB shot at the throughput of 100 (wph) is (1413.7)^{1/2}=37.6 (μm). When the electron beam size is a 37.6 (μm) square, the EB exposing unit 20C can perform EB exposure at the speed of 100 (wph). In this embodiment, the speed (throughput) of the EB exposure by the EB exposing unit 20C is set based on the speed of the EUV exposure by the EUV-exposure processing unit 1. The EB exposing unit 20C is configured to be capable of calculating electron beam size corresponding to the set speed of the EB exposure and performing the EB exposure with the calculated electron beam size. Consequently, an effect of improving throughput by limiting an EUV exposure area is directly obtained as a throughput improving effect of the entire exposing apparatus 100.

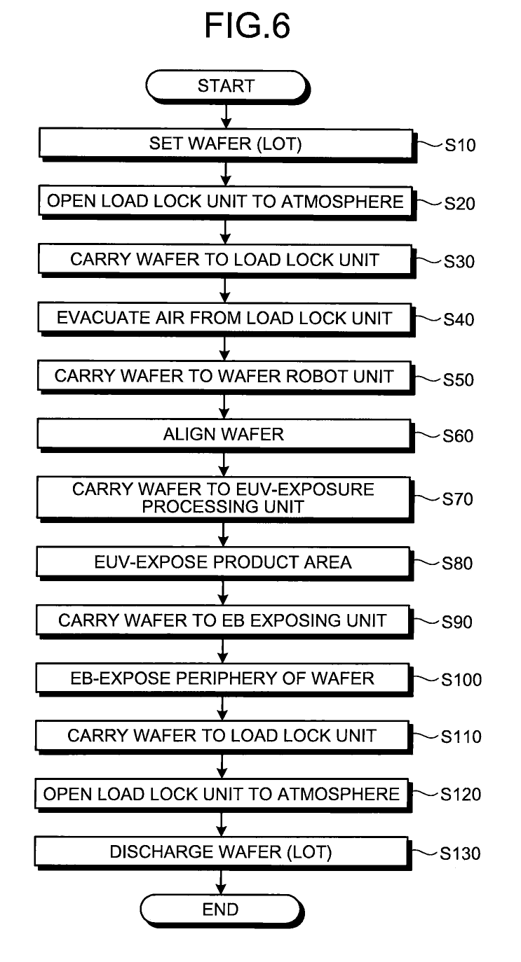

FIG. 6 is a flowchart of an exposure processing procedure for a wafer. The wafers 5 of one lot including a plurality of wafers are set on a load port (not shown) of the load lock unit 3 (step S10). The exposing apparatus 100 opens a carry-in port to the load port to open the load lock unit 3 to the atmosphere (step S20). The load lock unit 3 collectively carries the wafers 5 of one lot set on the load port into the load lock unit 3 (step S30). Because the wafers 5 are stored in the load lock unit 3 for each lot, turn around time (TAT) of exposure processing for one lot can be reduced.

After carrying the wafers 5 into the load lock unit 3, the load lock unit 3 closes the carry-in port to the load port and evacuate air from the load lock unit 3 (step S40). When a degree of vacuum in the load lock unit 3 reaches a predetermined degree of vacuum set in advance, the load lock unit 3 opens the gate valve arranged between the load lock unit 3 and the wafer loader 20B. The wafer loader 20B of the wafer robot unit 2 carries in the wafer 5 in the load lock unit 3 and places the wafer 5 on the wafer stage 22B (step S50). The wafer loader 20B carries the wafer 5 placed on the wafer stage 22B to the alignment unit 20A. The alignment unit 20A places the wafer 5, which is carried from the wafer loader 20B, on the wafer stage 22A and aligns the wafer 5 (step S60).

The alignment unit 20A carries the aligned wafer 5 to the EUV-exposure processing unit 1 (step S70). The EUV-exposure processing unit 1 places the wafer 5 on the wafer stage 11 and EUV-exposes a product area (an EUV exposure area) of the wafer 5 (step S80).

When the EUV exposure by the EUV-exposure processing unit 1 is finished, the EUV-exposure processing unit 1 carries the exposed wafer 5 to the EB exposing unit 20C (step S90). As the EB forming aperture 40 of the EB exposing unit 20C, the EB forming aperture 40 corresponding to the coverage of the product chip is selected and set. The EB-exposing unit 20C exposes the periphery (the EB exposure area) of the wafer 5 with EB formed by the set EB forming aperture 40. In other words, the EB exposing unit 20C irradiates an EB on an area not exposed by the EUV exposure to thereby perform peripheral exposure of the wafer 5 (step S100). The EB-exposing unit 20C performs the EB exposure while rotating the wafer 5 and controlling positions of a plurality of EB shots in the EB exposure area.

When the peripheral exposure of the wafer 5 is finished, the EB exposing unit 20C carries the wafer 5 to the load lock unit 3 (step S110). Thereafter, the exposing apparatus 100 EUV-exposes and EB-exposes the remaining wafers 5 carried into the load lock unit 3. Specifically, the exposing apparatus 100 performs the processing at steps S50 to S110.

The exposing apparatus 100 does not need to delay processing of the next wafer 5 until the processing at steps S50 to S100 is completed for one wafer 5. The exposing apparatus 100 starts the processing of the next wafer 5 as much as possible. For example, while an nth (n is a natural number) wafer 5 is EUV-exposed by the EUV-exposure processing unit 1, an (n+1)th wafer 5 is aligned by the alignment unit 20A. While the nth wafer 5 is EB-exposed by the EB exposing unit 20C, the (n+1)th wafer 5 is EUV-exposed by the EUV-exposure processing unit 1.

When the exposure processing (the EUV exposure and the EB exposure) for all the wafers 5 in the lot is finished, the load lock unit 3 is opened to the atmosphere (step S120). The load lock unit 3 collectively returns the wafers 5 of one lot to the load port or an unload port separately provided from the load port, discharges the wafers 5 to the outside (step S130), and finishes the exposure processing.

In this way, the EB exposure of the periphery is performed when the EUV exposure of the product chip section is finished. Therefore, it is possible to EUV-expose a product chip section of the next wafer 5 during the peripheral exposure. In other words, the exposing apparatus 100 EB-exposes the other wafers 5 while performing the EUV exposure, i.e., processes the EUV exposure and the EB exposure in parallel. This makes it possible to substantially reduce the TAT of the exposure processing. When the wafers 5 are stored in the load lock unit 3 for each lot and maintains a vacuum state, it is possible to further reduce the TAT of the exposure processing.

For example, when exposure time T_{EB} necessary for the peripheral exposure by an EB and exposure time T_{EUV} for the product chip section by an EUV are substantially the same, exposure time Tₜₒₜₐₗ necessary for processing all the wafers 5 in the lot is Tₜₒₜₐₗ=m×T_{EUV}+T_{EB}, where m (a natural number) represents the number of wafers 5 in the lot. Because T_{EUV} nearly equals T_{EB}, Tₜₒₜₐₗ=(m+1) T_{EUV}.

For example, when the EUV exposure time can be reduced 20% by omitting a peripheral shot in the EUV exposure, because T_{EUV}=0.8×T_{EUV}′, T_{EUV}′=1.25×T_{EUV} and Tₜₒₜₐₗ′=m×T_{EUV}′=1.25×m×T_{EUV}. When m=25 per one lot, m+1=26 and 1.25×m=31.25. It is seen by comparing 26 and 31.25 that the exposing method in the past requires processing time 1.2 times as long as that of the exposing method according to this embodiment (the method of omitting the peripheral shot in the EUV exposure).

In this embodiment, the peripheral exposure of the wafer 5 is performed by the EB irradiation column 25 set in the wafer loader unit (the wafer robot unit 2). Therefore, the peripheral exposure (imperfect shot) (essentially waste shots) of the wafer 5 by the EUV exposure is unnecessary and exposure throughput is improved.

The peripheral exposure of the wafer 5 by the EB exposure is performed while the wafer 5 is rotated. An EB pattern corresponding to pattern coverage of a product chip is formed and irradiated on the wafer 5. Therefore, it is possible to realize high-throughput EB exposure with the small EB exposing unit 20C.

Because the EB exposing unit 20C can be reduced in size, the EB exposing unit 20C can be easily set in a free space of the EUV-exposure processing unit 1. Therefore, an increase in foot print of the exposing apparatus 100 can be economically held down.

The EB exposing unit 20C has a configuration simpler than that of the EUV-exposure processing unit 1. Therefore, the exposing apparatus 100 is simpler than an exposing apparatus that exposes the wafer 5 using two EUV-exposure processing units 1.

In the above explanation of the embodiment, the wafers 5 are set on the load port for each lot and the wafers 5 are carried into the load lock unit 3 for each lot. However, these kinds of processing can also be performed by single-wafer processing (processing for each of the wafers 5). In this case, the wafers 5 are carried out from the load lock unit 3 to the load port by the single-wafer processing. For example, when the wafers 5 are carried out from the load lock unit 3 to the load port by the single-wafer processing, every time each of the wafers 5 returns from the wafer robot unit 2 to the load lock unit 3, the load lock unit 3 is opened to the atmosphere and the wafer is carried out to the load port.

In the above explanation of this embodiment, the alignment unit 20A aligns the wafer 5. However, the EUV-exposure processing unit 1 can also align the wafer 5. In this case, the wafer robot unit 2 does not have to include the alignment unit 20A.

In the above explanation of this embodiment, time required for the EB exposure is shorter than time required for the EUV exposure. However, time required for the EB exposure can be longer than time required for the EUV exposure.

In the above explanation of this embodiment, the EB exposure is performed after the EUV exposure is performed for each wafer 5. However, the EUV exposure can be performed after the EB exposure is performed. The EB exposure of the last wafer 5 in the lot can be performed while the EUV exposure of the first wafer 5 in the lot is performed. In this case, as in the embodiment, the (n+1)th wafer 5 is EUV-exposed while the nth wafer 5 is EB-exposed. The last wafer 5 is carried out to the load lock unit 3 without being EB-exposed after being EUV-exposed. This makes it possible to reduce processing time for the wafers 5 of one lot. The exposing apparatus 100 can continuously process a plurality of lot to exposure processing.

In the above explanation of this embodiment, the peripheral exposure of the wafer 5 is performed by the EB exposure. However, the peripheral exposure of the wafer 5 can also be performed by using excimer laser beams such as KrF and ArF. In this case, for example, an exposing apparatus that irradiates the excimer laser beams on the periphery of the wafer 5 is provided in the wafer robot unit 3.

In the above explanation of this embodiment, the wafer robot unit 2 includes one EB exposing unit 20C. However, the wafer robot unit 2 can also include a plurality of EB exposing units 20C.

As explained above, according to this embodiment, the product chip section of the next wafer 5 can be EUV-exposed while the peripheral exposure of the wafer 5 is performed by the EB exposure. Therefore, it is possible to easily improve the throughput of wafer exposure.

The EB exposing unit 20C performs the peripheral exposure of the wafer 5 while rotating the wafer 5. Therefore, the EB exposing unit 20C can be reduced in size. When the peripheral exposure of the wafer 5 is performed, an EB irradiation pattern is formed to have coverage same as that of the product chip section. Therefore, a coverage distribution of the entire wafer can be uniform. Consequently, it is possible to uniformly machine the wafer 5 in the plane of the wafer 5. The yield of product chips is improved.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A wafer exposing method comprising EUV-exposing a product area, which is formed as a product chip, on a wafer and EB-exposing a peripheral area on the wafer, wherein
the EB exposure of a wafer different from the wafer being EUV-exposed is performed while the EUV exposure of the wafer is performed.

2. The wafer exposing method according to claim 1, wherein, the peripheral area of the wafer is EB-exposed while the wafer is rotated in a plane of the wafer.

3. The wafer exposing method according to claim 1, wherein processing time for EB-exposing the peripheral area of the wafer is shorter than processing time for EUV-exposing the product area of the wafer.

4. The wafer exposing method according to claim 1, wherein electron beam size used in performing the EB exposure is size with which processing time for EB-exposing a singularity of the wafer is shorter than processing time for EUV-exposing the one wafer.

5. The wafer exposing method according to claim 1, wherein pattern density of the product area to be EUV-exposed and pattern density of the peripheral area to be EB-exposed are the same.

6. The wafer exposing method according to claim 5, wherein, when the EB exposure is performed, an EB forming aperture that can form a pattern having coverage same as coverage of a pattern formed by using an EUV shot is used.

7. The wafer exposing method according to claim 1, wherein, when the wafers in a wafer lot are EUV-exposed and EB-exposed, wafers other than a wafer to be EUV-exposed last in the lot are EB-exposed after being EUV-exposed, and the wafer to be EUV-exposed last in the lot is EB-exposed while a first wafer in the lot is EUV-exposed.

8. The wafer exposing method according to claim 1, wherein, when the wafers in a wafer lot are EUV-exposed and EB-exposed, wafers other than a wafer to be EB-exposed last in the lot are EUV-exposed after being EB-exposed, and the wafer to be EB-exposed last in the lot is EUV-exposed while a first wafer in the lot is EB-exposed.

9. An EUV exposing apparatus comprising:
an EUV-exposure processing unit that EUV-exposes a product area, which is formed as a product chip, on a wafer; and
an EB-exposure processing unit that EB-exposes a peripheral area on the wafer, wherein
the EB-exposure processing unit EB-exposes, while the EUV-exposure processing unit EUV-exposes a wafer, a wafer different from the wafer EUV-exposed by the EUV-exposure processing unit.

10. The EUV exposing apparatus according to claim 9, wherein
the EB-exposure processing unit includes a wafer stage that places the wafer thereon and rotates the wafer when the wafer is EB-exposed, and
in performing the EB exposure, the EB-exposure processing unit EB-exposes the peripheral area of the wafer while rotating the wafer on the wafer stage in a plane of the wafer.

11. The EUV exposing apparatus according to claim 9, wherein processing time for the EB-exposure processing unit to EB-expose the peripheral area of the wafer is shorter than processing time for the EUV-exposure processing unit to EUV-expose the product area of the wafer.

12. The EUV exposing apparatus according to claim 9, wherein electron beam size used by the EB-exposure processing unit in performing the EB exposure is size with which processing time for the EB-exposure processing unit to EB-expose a singularity of the wafer is shorter than processing time for the EUV-exposure processing unit to EUV-expose the one wafer.

13. The EUV exposing apparatus according to claim 9, wherein pattern density of the product area to be EUV-exposed by the EUV-exposure processing unit and pattern density of the peripheral area to be EB-exposed by the EB-exposure processing unit are the same.

14. The EUV exposing apparatus according to claim 13, wherein the EB-exposure processing unit includes an EB forming aperture that can form a pattern having coverage same as coverage of a pattern formed by using an EUV shot and performs the EB exposure using the EB forming aperture.

15. The EUV exposing apparatus according to claim 9, wherein, when the EUV-exposure processing unit and the EB-exposure processing unit EUV-exposes and EB-exposes the wafers in a wafer lot, the EB-exposure processing unit EB-exposes wafers other than a wafer to be EUV-exposed last by the EUV-exposure processing unit in the lot after EUV-exposing the wafers and EB-exposes the wafer to be EUV-exposed last by the EUV-exposure processing unit in the lot while the EUV-exposure processing unit EUV-exposes a first wafer in the lot.

16. The EUV exposing apparatus according to claim 9, wherein, when the EUV-exposure processing unit and the EB-exposure processing unit EUV-exposes and EB-exposes the wafers in a wafer lot, the EUV-exposure processing unit EUV-exposes wafers other than a wafer to be EB-exposed last by the EB-exposure processing unit in the lot after EB-exposing the wafers and EUV-exposes the wafer to be EB-exposed last by the EB-exposure processing unit in the lot while the EB-exposure processing unit EB-exposes a first wafer in the lot.

17. An EB exposing apparatus comprising:
an EUV-exposure processing unit that EUV-exposes a product area, which is formed as a product chip, on a wafer; and
an EB-exposure processing unit that EB-exposes a peripheral area on the wafer, wherein
the EUV-exposure processing unit EUV-exposes, while the EB-exposure processing unit EB-exposes a wafer, a wafer different from the wafer EB-exposed by the EB-exposure processing unit.

18. The EB exposing apparatus according to claim 17, wherein
the EB-exposure processing unit includes a wafer stage that places the wafer thereon and rotates the wafer when the wafer is EB-exposed, and
in performing the EB exposure, the EB-exposure processing unit EB-exposes the peripheral area of the wafer while rotating the wafer on the wafer stage in a plane of the wafer.

19. The EB exposing apparatus according to claim 17, wherein processing time for the EB-exposure processing unit to EB-expose the peripheral area of the wafer is shorter than processing time for the EUV-exposure processing unit to EUV-expose the product area of the wafer.

20. The EB exposing apparatus according to claim 17, wherein pattern density of the product area to be EUV-exposed by the EUV-exposure processing unit and pattern density of the peripheral area to be EB-exposed by the EB-exposure processing unit are the same.
